(19) United States
(12) Patent Application Publication
(10) Pub. No.: US 2008/0317968 A1
(43) Pub. Date: Dec. 25, 2008

(54) TILTED PLASMA DOPING

(75) Inventors: Vikram SINGH, North Andover, MA (US); James Steve Buff, Brookline, NH (US); Rajesh Dorai, Woburn, MA (US)

Correspondence Address: VARIAN SEMICONDUCTOR EQUIPMENT ASSC., INC., 35 DORY RD., GLOUCESTER, MA, 01930-2297, US

(73) Assignee: VARIAN SEMICONDUCTOR EQUIPMENT ASSOCIATES, INC., Gloucester, MA (US)

(21) Appl. No.: 12/200,178

(22) Filed: Aug. 28, 2008

Related U.S. Application Data
(62) Division of application No. 10/908,009, filed on Apr. 25, 2005.

(51) Int. Cl. C23C 14/00

(52) U.S. Cl. 427/523

(57) ABSTRACT

A plasma doping apparatus includes a chamber and a plasma source that generates ions in the chamber from a dopant gas. A grating is positioned in the chamber. A platen for supporting a target is positioned in the chamber. At least one of the grating and the target are oriented so that dopant ions extracted from the grating impact the target at a non-normal angle of incidence.

### PRIORITY

This application is a divisional application of U.S. patent application Ser. No. 10/908,009 filed Apr. 25, 2005 entitled “Tilted Plasma Doping,” which is incorporated in its entirety by reference.

### INTRODUCTION

The section headings used herein are for organizational purposes only and should not to be construed as limiting the subject matter described in the present application.

Conventional beam-line ion implanters accelerate ions with an electric field. The accelerated ions are filtered according to their mass-to-charge ratio to select the desired ions for implantation. Plasma doping or plasma immersion ion implantation (PIII) immerses the target in a plasma containing dopant ions and biases the target with a series of negative voltage pulses. The negative bias on the target repels the electrons from the target surface thereby creating a sheath of positive ions. The sheath of positive ions creates an electric field between the sheath boundary and the target surface. The electric field accelerates ions towards the target thereby implanting the ions into the target surface.

### BRIEF DESCRIPTION OF THE DRAWINGS

The aspects of this invention may be better understood by referring to the following description in conjunction with the accompanying drawings, in which like numerals indicate like structural elements and features in various figures. The drawings are not necessarily to scale. The skilled artisan will understand that the drawings, described below, are for illustration purposes only. The drawings are not intended to limit the scope of the present teachings in any way.

FIG. 1 illustrates one embodiment of a plasma doping apparatus with a tilted grating according to the present invention.

FIG. 2 illustrates a plasma doping apparatus with a tilted platen according to the present invention.

FIG. 3 illustrates a plasma doping apparatus with a saw tooth shaped grating according to the present invention.

FIG. 4 shows a computer simulation of extracted ions that illustrates the effects of varying the aperture size of the grating.

FIG. 5 shows a computer simulation of extracted ions that illustrates the interaction between two extracted ion beams.

### DETAILED DESCRIPTION

While the present teachings are described in conjunction with various embodiments and examples, it is not intended that the present teachings be limited to such embodiments. On the contrary, the present teachings encompass various alternatives, modifications and equivalents, as will be appreciated by those of skill in the art.

For example, the methods and apparatus of the present invention can be applied to any ion beam application, such as ion beam etching and other materials processing applications, and are not limited to plasma doping. Also, one skilled in the art will appreciate that the apparatus and methods of the present invention are not limited to shallow angle dopant implants and can, in fact, be used to implant dopant ions at any non-normal angle of incidence. In addition, some embodiments are described in connection with a tilted grating or a tilted target. One skilled in the art will appreciate that the apparatus and methods of the present invention can be practiced with a target and a grating positioned in numerous orientations as long as the dopant ions extracted from the grating impact the target at the desired non-normal angle of incidence.

It should be understood that the individual steps of the methods of the present invention may be performed in any order and/or simultaneously as long as the invention remains operable. Furthermore, it should be understood that the apparatus of the present invention can include any number or all of the described embodiments as long as the invention remains operable.

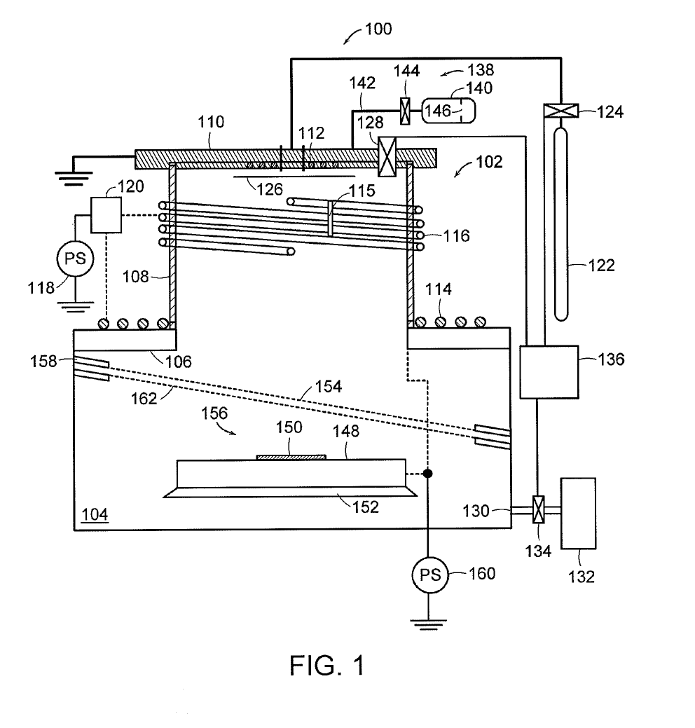

FIG. 1 illustrates one embodiment of a plasma doping apparatus 100 with a tilted grating according to the present invention. The plasma doping apparatus 100 includes a plasma source 102 that is attached to a process chamber 104. Any plasma source that creates the required density of dopant ions can be used. The plasma source 102 shown in FIG. 1 is a RF inductively coupled plasma source that is described in more detail in U.S. patent application entitled “RF Plasma Source with Conductive Top Section,” Ser. No. 10/905,172, filed on Dec. 20, 2004, which is assigned to the present assignee. The entire specification of U.S. patent application Ser. No. 10/905,172 is incorporated herein by reference. The plasma source 102 can be any of numerous other types of plasma sources. For example, the plasma source 102 can be an inductively coupled plasma source, a capacitively coupled plasma source, a toroidal plasma source, a helicon plasma source, a DC plasma source, a remote plasma source, and a downstream plasma source.

The plasma source 102 includes a first section 106 formed of a dielectric material that extends in a horizontal direction. A second section 108 is formed of a dielectric material that extends a height from the first section 106 in a vertical direction. In the embodiment shown in FIG. 1, the second section 108 is formed in a cylindrical shape. It is understood that one skilled in the art will appreciate that the first section 106 does not need to extend in exactly a horizontal direction and the second section 108 does not need to extend in exactly a vertical direction.

The dimensions of the first and the second sections 106, 108 of the plasma source 102 can be selected to improve the uniformity of plasmas generated in the plasma source 102. In one embodiment, a ratio of the height of the second section 108 in the vertical direction to the length across the second section 108 in the horizontal direction is about between 1.5 and 5.5.

The dielectric materials in the first and second sections 106, 108 provide a medium for transferring the RF power from the RF antenna to a plasma inside the plasma source 102. In one embodiment, the dielectric material used to form the first and second sections 106, 108 is a high purity ceramic material that is chemically resistant to the dopant gases and that has good thermal properties. For example, in some embodiments, the dielectric material is 99.6% Al₂O₃ or AlN. In other embodiments, the dielectric material is Yittria and YAG.

A top section 110 of the plasma source 102 is formed of a conductive material that extends across the top of the second section 108 in the horizontal direction. In some embodiments, the conductive material is aluminum. The material used to form the top section 110 is typically chosen to be chemically resistant to the dopant gases. The conductivity of the material used to form the top section 110 can be chosen to be high enough to dissipate a substantial portion of the heat load and to minimize charging effects that results from secondary electron emission.

In one embodiment, the top section 110 is coupled to the second section 108 with high temperature halogen resistant O-rings that are made of fluorocarbon polymer, such as an O-ring formed of Chemrz and/or Kalrex materials. The top section 110 is typically mounted to the second section 108 in a manner that minimizes compression on the second section 108, but that also provides enough compression to seal the top section 110 to the second section 108.

Some plasma doping processes generate a considerable amount of non-uniformly distributed heat on the inner surfaces of the plasma source 102 because of secondary electron emissions. The non-uniformly distributed heat creates temperature gradients on the inner surfaces of the plasma source 102 that can be high enough to cause thermal stress points within the plasma source 102 that can result in a failure. In some embodiments, the top section 110 comprises a cooling system that regulates the temperature of the top section 110 in order to dissipate the heat load generated during processing. The cooling system can be a fluid cooling system that includes cooling passages 112 in the top section 110 that circulates a liquid coolant from a coolant source.

A RF antenna is positioned proximate to at least one of the first section 106 and the second section 108 of the plasma source 102. The plasma doping apparatus 100 illustrated in FIG. 1 illustrates a planar coil antenna 114 positioned adjacent to the first section 106 of the plasma source 102 and a helical coil antenna 116 surrounding the second section 108 of the plasma source 102. However, the plasma source 102 can have many different antenna configurations.

At least one of the planar coil antenna 114 and the helical coil antenna 116 is an active antenna. The term “active antenna” is herein defined as an antenna that is driven directly by a power supply. In other words, a voltage generated by a power supply is directly applied to an active antenna. In some embodiments, at least one of the planar coil antenna 114 and the helical coil antenna 116 is formed such that it can be liquid cooled. Cooling at least one of the planar coil antenna 114 and the helical coil antenna 116 will reduce temperature gradients caused by the RF power propagating in the RF antennas 114, 116.

In some embodiments, one of the planar coil antenna 114 and the helical coil antenna 116 is a parasitic antenna. The term “parasitic antenna” is defined herein to mean an antenna that is in electromagnetic communication with an active antenna, but that is not directly connected to a power supply. In other words, a parasitic antenna is not directly excited by a power supply, but rather is excited by an active antenna. In some embodiments of the invention, one end of the parasitic antenna is electrically connected to ground potential in order to provide antenna tuning capabilities. In this embodiment, the parasitic antenna includes a coil adjuster 115 that is used to change the effective number of turns in the parasitic antenna coil. Numerous different types of coil adjusters, such as a metal short, can be used.

A RF power supply 118 is electrically connected to at least one of the planar coil antenna 114 and the helical coil antenna 116. The RF power supply 118 is electrically coupled to at least one of the RF antennas 114, 116 by an impedance matching network 120 that maximizes the power transferred from the RF power supply 118 to the RF antennas 114, 116. Dashed lines from the output of the impedance matching network 120 to the planar coil antenna 114 and the helical coil antenna 116 are shown to indicate that electrical connections can be made from the output of the impedance matching network 120 to either or both of the planar coil antenna 114 and the helical coil antenna 116.

A gas source 122 is coupled to the plasma source 102 through a proportional valve 124. In some embodiments, a gas baffle 126 is used to disperse the gas into the plasma source 102. A pressure gauge 128 measures the pressure inside the plasma source 102. An exhaust port 130 in the process chamber 104 is coupled to a vacuum pump 132 that evacuates the process chamber 104. An exhaust valve 134 controls the exhaust conductance through the exhaust port 130. A gas pressure controller 136 is electrically connected to the proportional valve 124, the pressure gauge 128, and the exhaust valve 134. The gas pressure controller 136 maintains the desired pressure in the plasma source 102 and the process chamber 104 by controlling the exhaust conductance with the exhaust valve 134 and controlling the dopant gas flow rate with the proportional valve 124 in a feedback loop that is responsive to the pressure gauge 128.

In some embodiments, a ratio control of trace gas species is provided by a mass flow meter (not shown) that is coupled in-line with the dopant gas that provides the primary dopant gas species. Also, in some embodiments, a separate gas injection means (not shown) is used for in-situ conditioning species. For example, silicon doped with an appropriate dopant can be used to provide a uniform coating in the process chamber 104 that reduces contaminants. Furthermore, in some embodiments, a multi-port gas injection means (not shown) is used to provide gases that cause neutral chemistry effects that result in across wafer variations.

In some embodiments, the plasma doping apparatus 100 includes a plasma igniter 138. Numerous types of plasma igniters can be used with the plasma doping apparatus of the present invention. In one embodiment, the plasma igniter 138 includes a reservoir 140 of strike gas, which is a highly-ionizable gas, such as argon (Ar), which assists in igniting the plasma. The reservoir 140 is coupled to the plasma chamber 104 with a high conductance gas connection 142. A burst valve 144 isolates the reservoir 140 from the process chamber 104. In another embodiment, a strike gas source is plumbed directly to the burst valve 144 using a low conductance gas connection. In some embodiments, a portion of the reservoir 140 is separated by a limited conductance orifice 146 or metering valve that provides a steady flow rate of strike gas after the initial high-flow-rate burst.

A platen 148 is positioned in the process chamber 104 a height below the top section 110 of the plasma source 102. The platen 148 holds a target 150, such as a substrate, for ion implantation. In many embodiments, the target 150 is electrically connected to the platen 148. In the embodiment shown in FIG. 1, the platen 148 is parallel to the plasma source 102. However, in other embodiments of the present invention, the platen 148 is tilted with respect to the plasma source 102.

In one embodiment, the platen 148 is mechanically coupled to a movable stage 152. In one embodiment, the movable stage 152 is a translation stage that scans the target 150 in at least one direction. In one embodiment, the movable stage 152 is a dither generator or an oscillator that dithers or oscillates the target 150. In one embodiment, the movable stage 152 is a rotation stage that rotates the target 150. The translation, dithering, oscillation, and/or rotation motion reduces or eliminates shadowing effects and improves the uniformity of the ion beam flux impacting the surface of the target 150. The rotation motion can also be used to control multi-step dopant ion implants.

A grating 154 is positioned in the process chamber 104 adjacent to the platen 148. The term “grating” is defined herein as a structure that forms a barrier to the plasma generated by the plasma source 102 and that defines passages through which the ions in the plasma pass through when the grating is properly biased. The region 156 between the grating 154 and the platen 148 can be dimensioned to reduce the number of ion collisions in the region 156. The target 150 and the grating 154 are oriented together so that the dopant ions extracted from the grating 154 impact the target 150 at a desired non-normal angle of incidence. In the embodiment shown in FIG. 1, the grating 154 is oriented at the desired non-zero angle of incidence.

In one embodiment, the grating 154 is formed of a non-metallic material or a metallic material that is completely coated with a non-metallic material. For example, the grating 154 can be formed of doped silicon (poly or single crystal), silicon carbide, and silicon coated aluminum. Such materials work well with hydride and fluoride chemistries.

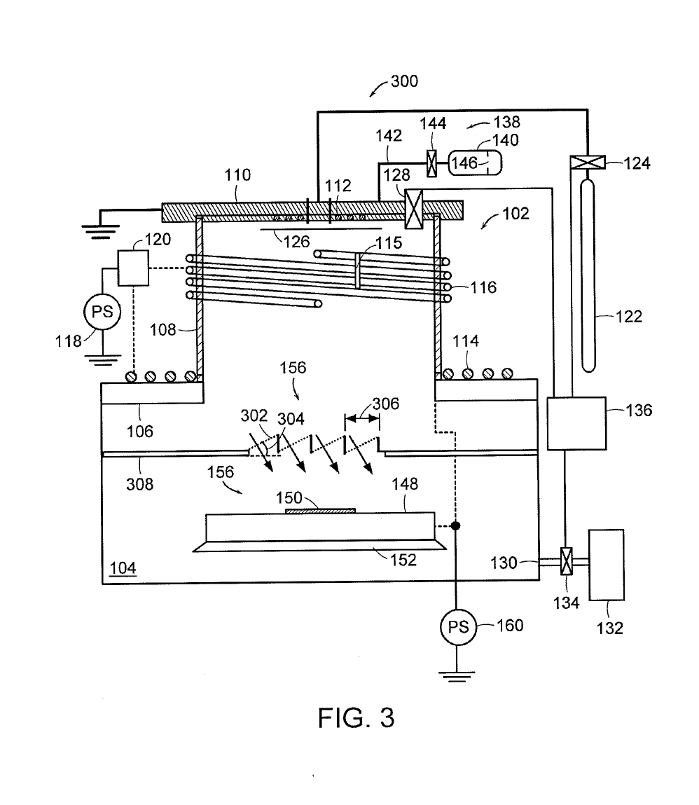

The grating 154 can be straight as shown in FIG. 1 or can be formed in numerous other shapes, such as a saw tooth shape that is described in connection with FIG. 3. In one embodiment, the grating 154 is a grid with apertures. In another embodiment, the grating 154 is a structure that defines slots. In yet another embodiment, the grating 154 is a perforated mesh structure. A fill factor of the grating 154 can be selected to achieve a certain ion current at the surface of the target 150 or to limit the extent of the plasma into the region 156 between the grating 154 and the platen 148. The fill factor can also be selected to prevent formation of a plasma in the region 156 between the grating 154 and the platen 148. The term “fill factor” is defined herein to mean the ratio of the open area of the grating 154 that passes dopant ions to the solid area of the grating 154 that blocks the ions.

The area of the grating 154 is typically greater than or equal to the area of the target 150 being implanted. The region 156 between the grating 154 and the target 150 can be pumped to a lower pressure than the plasma source 102 in order to prevent scattering of ions in the region 156 caused by collisions with background dopant gas molecules. The region 156 between the grating 154 and the target 150 can also be pumped to a lower pressure than the plasma source 102 in order to prevent formation of a plasma in the region 156 between the grating 154 and the target 150.

In one embodiment, the grating 154 is mechanically coupled to a movable stage 158. The movable stage 158 can be a dither generator or an oscillator that dithers or oscillates the grating 154. In this embodiment, the movable stage 158 dithers or oscillates the grating 154 in a direction that is perpendicular to slots in the grating 154. The movable stage 158 dithers or oscillates the grating 154 in two directions if the grating 154 forms apertures or a mesh pattern. The movable stage 158 can also be a rotation stage that rotates the grating 154. The translation, dithering, oscillation, and/or rotation motions reduce or eliminate shadowing effects and improve the uniformity of the ion beam flux impacting the surface of the target.

A bias voltage power supply 160 is used to bias at least one of the grating 154 and the target 150 so that dopant ions in the plasma are extracted from the grating 154 and impact the target 150 at the non-normal angle of incidence. The bias voltage power supply 160 can be a DC power supply, a pulsed power supply, or a RF power supply. An output of the bias voltage power supply 160 is electrically connected to at least one of the grating 154 and the target 150. Dashed lines from the output of the bias voltage power supply 160 to the grating 154 and to the target 150 are shown to indicate that electrical connections can be made from the output of the bias voltage power supply 160 to either or both of the grating 154 and the target 150.

In the embodiment shown in FIG. 1, the output of the bias voltage power supply 160 is electrically connected to both the grating 154 and the target 150 so that the grating 154 and the target 150 are at substantially the same potential. In this embodiment, the region 156 between the grating 154 and the target 150 is at substantially a constant potential and thus is a field free region. However, one skilled in the art will appreciate that the plasma doping apparatus of FIG. 1 has many different possible biasing configurations.

In one embodiment, an electrode 162 is positioned proximate to the grating 154. The electrode 162 can be positioned adjacent to the grating 154 as shown in FIG. 1. In this embodiment, the electrode 162 has the same fill factor and grating pattern as the grating 154 and is aligned to the grating 154 so that ions pass through both the grating 154 and the electrode 162. The electrode 162 is biased at substantially the same potential as the grating 154 so that at least a portion of the electrons generated by the target 150 are absorbed by the electrode 162.

In one embodiment, a magnet or any source of magnetic field is positioned proximate to the grating 154 and to the target 150 so that a magnetic field is generated in the region 156 between the grating 154 and the target 150. The magnetic field traps at least a portion of the electrons that are located proximate to the target 150.

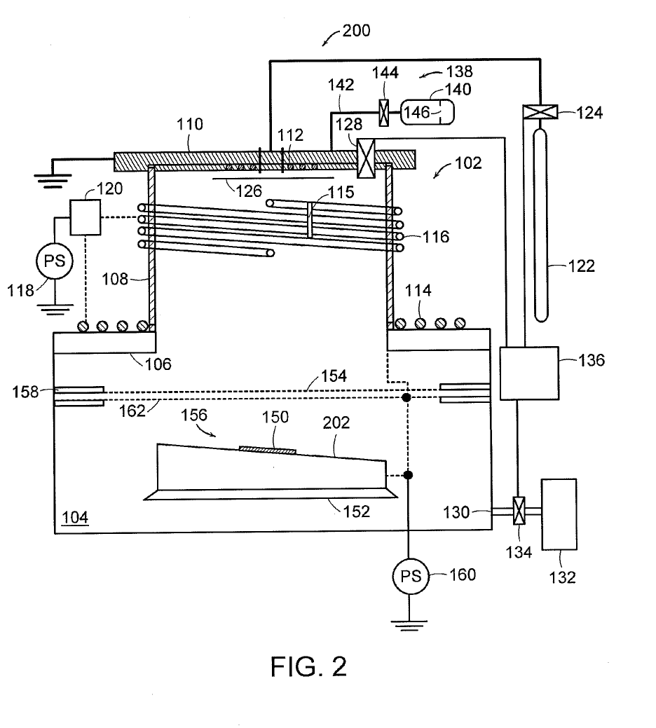

FIG. 2 illustrates a plasma doping apparatus 200 with a tilted platen 202 according to the present invention. The plasma doping apparatus 200 is similar to the plasma doping apparatus 100 except that the grating 154 is positioned parallel to the plasma source 102 and the platen 202 is designed so that the surface of the target 150 is positioned at a desired non-zero angle with respect to the grating 154. In other embodiments, the grating 154 is positioned at a non-zero angle with respect to the plasma source 102 and the platen 202 is designed so that the surface of the target 150 is positioned at a non-zero angle with respect to both the grating 154 and the plasma source 102.

The platen 202 can be mechanically translated, dithered, oscillated, and/or rotated with the movable stage 152 as described in connection with FIG. 1. The grating 154 can also be mechanically translated, dithered, oscillated, and/or rotated with the movable stage 152 as described in connection with FIG. 1. The translation, dithering, oscillation, and/or rotating of at least one of the target 150 and the grating 154 can minimizes or eliminate ion shadowing effects and, therefore, can improve the uniformity of the ion flux impacting the surface of the target 150.

FIG. 3 illustrates one embodiment of a plasma doping apparatus 300 with a saw tooth shaped grating 302 according to the present invention. The aperture or slot size, the angle 304 of the saw tooth pattern, and the length 306 of the saw tooth pattern are chosen so that relatively uniform ion flux impacts the surface of the target 150. In one embodiment, the saw tooth shaped grating 302 is designed to minimize or eliminate the ion shadowing effects of the grating 302.

The saw tooth shaped grating 302 can be mechanically coupled to a movable stage 308 that scans the grating 302 in at least one direction. In one embodiment, the movable stage 308 is a dither generator or oscillator that dithers or oscillates the grating 302. In this embodiment, the grating 302 is dithered or oscillated in a direction that is perpendicular to slots in the grating 302. The grating 302 is dithered or oscillated in two directions if the grating forms apertures or a mesh pattern. In one embodiment, the movable stage 308 is a rotation stage that rotates the grating 302. The translation, dithering, oscillation, and/or rotation motion reduces or eliminates shadowing effects and improves the uniformity of the ion beam flux impacting the surface of the target 150.

The operation of the plasma doping apparatus 100, 200, 300 described in connection with FIGS. 1-3 is similar. In operation, the plasma source 102 is evacuated to high vacuum. The dopant gas is then injected into the plasma source 102 by the proportional valve 124 and exhausted from the process chamber 104 by the vacuum pump 132. In one embodiment, the dopant gas is symmetrically injected into the plasma source 102 and symmetrically pumped out of the process chamber 104. The gas pressure controller 136 is used to maintain the desired gas pressure for a desired dopant gas flow rate and exhaust conductance.

The RF power supply 118 generates a RF signal that is applied to the RF antennas 114, 116. In some embodiments, one of the planar coil antenna 114 and the helical coil antenna 116 is a parasitic antenna and the parasitic antenna is tuned in order to improve or maximize the uniformity of the plasma. In some embodiments, the RF source 118 generates a relatively low frequency RF signal. Using a relatively low frequency RF signal will minimize capacitive coupling and, therefore will reduce sputtering of the chamber walls and the resulting contamination. For example, in these embodiments, the RF power supply 118 generates RF signals below 27 MHz, such as 400 kHz, 2 MHz, 4 MHz or 13.56 MHz.

The RF signal applied to the RF antennas 114, 116 generates a RF current in the RF antennas 114, 116. Electromagnetic fields induced by the RF currents in the RF antennas 114, 116 couple through at least one of the dielectric material forming the first section 106 and the dielectric material forming the second section 108 and into the plasma source 102. The electromagnetic fields induced in the plasma source 102 excite and ionize the dopant gas molecules. Plasma ignition occurs when a small number of free electrons move in such a way that they ionize some dopant gas molecules. The ionized dopant gas molecules release more free electrons that ionize more gas molecules. The ionization process continues until a steady state of ionized gas and free electrons are present in the plasma.

Plasma ignition is difficult for some dopant gases, such as diborane in helium (15% B₂H₆ in 85% He). For these gases, it is desirable to use a strike gas to initiate the plasma. In one embodiment, a strike gas, such as argon (Ar) is controllably introduced into the process chamber 104 at a predetermined time by opening and then closing the burst valve 144. The burst valve 144 passes a short high-flow-rate burst of strike gas into the plasma source 102 in order to assist in igniting the plasma.

The RF source 102 resonates RF currents in the RF antennas 114, 116. The RF current in the RF antennas 114, 116 induces RF currents into the plasma source 102. The RF currents in the plasma source 102 excite and ionize the dopant gas so as to generate a plasma in the plasma source 102. The plasma is confined in the plasma chamber 102 by the grating 154, 302.

At least one of the grating 154, 302 and the target 150 are biased so that dopant ions are extracted from the grating 154, 302 and impact the target 150 at the desired non-normal angle of incidence. Ions in the plasma are accelerated through the apertures or slots in the grating 154, 302. Any plasma between the grating 154, 302 and the target 150 will extinguish very rapidly (depending upon the background gas, this time can vary from microseconds to milliseconds). When the bias voltage is extinguished, the plasma will diffuse through the apertures or slots and neutralize at least some of the charge on the surface of the target 150.

Most of the extracted dopant ions impact the target 150 with an energy that is approximately equal to the sum of the bias voltage and the plasma potential. There may be some relatively low energy thermal ions that are present in residual plasma existing between the grating 154, 302 and the target 150. These ions are trapped between the grating 154, 302 and the target 150 and generally do not impact the target 150. Many of the secondary electrons that are generated by ions impacting the target 150 are absorbed by the positive potential of the ions. Electrons above the grating 154, 302 are quickly repelled by the negative voltage on the grating 154, 302. When the bias voltage is extinguished, the plasma diffuses through the slots and neutralizes charge on the surface of the target 150.

The non-normal angle of incidence can be adjusted for the specific application. For example, relatively low angles of incidence are required for some source drain extension implants for devices that use a diffusionless annealing process. Low to high tilt angles are required to perform side-wall doping for some devices that have trench and barrier structures and for FinFET devices depending upon the particular device structure.

The non-normal angle of incidence can also be chosen to achieve certain ion implant parameters. For example, the non-normal angle of incidence can be chosen to achieve a predetermined lateral straggle of dopant ions in the target 150. Also, the non-normal angle of incidence can be chosen to achieve a predetermined channeling of dopant ions in the target 150 or to reduce the channeling of dopant ions in the target 150.

In the embodiments shown in FIGS. 1-3, the grating 154, 302 and the target 150 are biased at the same potential so as to form a field free region 156 between the grating 154, 302 and the target 150. There are many other biasing configurations. For example, the grating 154, 302 can be biased relative to the target 150. Also, the grating 154, 302 and the target 150 can be biased synchronous in time or asynchronous in time. Also, one of the grating 154, 302 and the target 150 can be biased and the other can be at a floating potential.

In one embodiment, at least one of the grating 154, 302 and the target 150 are biased by pulsing the at least one of the grating 154, 302 and the target 150 at a pulse frequency. In embodiments that include movable stages 152, 158, 308 such as, translation stages, oscillators, and/or dither generators that are mechanically coupled to at least one of the grating 154, 302 and the target 150, the pulse frequency of the bias voltage can be chosen to be proportional to the scan velocity, dither frequency or oscillation frequency of the movable stage 152, 158, 308.

At least one of the grating 154, 302 and the target 150 can be biased to a potential that at least partially neutralizes charge on or proximate to the target 150. Also, at least one of the grating 154, 302 and the target 150 can be biased to a potential that is positive with respect to the grating 154, 302 in order to contain secondary electrons. In addition, the grating 154, 302 can be periodically grounded so as to at least partially neutralize charge on or proximate to the target 150.

The method of plasma doping according to the present invention can have relatively high throughput. The time at which the grating 154, 302 and the target 150 need to be biased to achieve the desired ion implant is generally independent on the dimensions of the target 150. Also, the method of plasma doping according to the present invention can produce shallow junctions more economically and with higher efficiency than conventional low energy beam line doping.

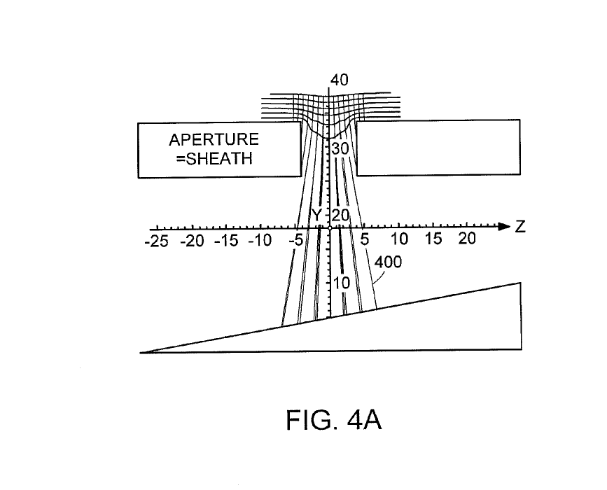

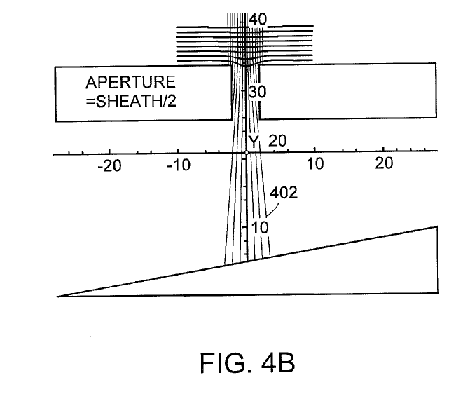

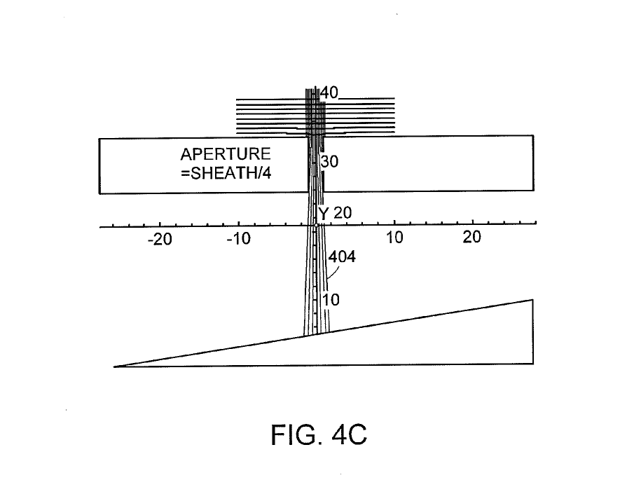

FIG. 4 shows a computer simulation of extracted ions that illustrates the effects of varying the aperture size of the grating 154, 302. The grating apertures must be relatively small in order to prevent dispersion of the extracted ions that results from the electric field penetrating through the aperture and into the field free region between the grating 154, 302 and the target 150. Also, the grating apertures must be relatively small to prevent a loss of electrons from the plasma.

Furthermore, the grating apertures must be relatively small in order to maintain the desired angle of impact on the surface of the target 150. Typically the ions impacting the surface of the target 150 have a small angular distribution because the trajectory of extracted ions is bent along the edges of the grating 154. The bending of the trajectory of extracted ions causes some extracted ions to impact the surface of the target 150 at angles that are different from the tilt angle or desired angle of impact. Decreasing the size of the apertures in the grating 154, 302 will decrease the angular distribution of the extracted ions. However, decreasing the size of the apertures in the grating 154, 302 will also reduce the ion current.

FIG. 4A shows a computer simulation 400 of extracted ions passing through the grating 154, 302 having a slot or an aperture width that is about the same dimension as the plasma sheath thickness. The computer simulation 400 shows that the angular distribution of extracted ions is about ±10 degrees. The computer simulation 400 indicates that slot and aperture widths that are greater than or equal to the plasma sheath thickness produce extracted ion angular distributions that are high enough to significantly change the implant profile.

FIG. 4B shows a computer simulation 402 of extracted ions passing through a grating 154, 302 having a slot or an aperture width that is about one-half the plasma sheath thickness. The computer simulation 402 shows that the angular distribution of the extracted ions is about ±4.5 degrees. The extracted ion current per slot or aperture is lower than the extracted ion current per slot or aperture shown in FIG. 4A where the slot or the aperture width is about the same dimension as the plasma sheath thickness by about a factor of two. However, the total ion current extracted from the grating 154, 302 depends upon the fill factor of the grating.

FIG. 4C shows a computer simulation 404 of extracted ions passing through a grating 154, 302 having a slot or an aperture width that is about one fourth the plasma sheath thickness. The computer simulation shows that the angular distribution of the extracted ions is about ±2 degrees. The extracted ion current per slot or aperture is lower than the extracted ion current per slot or aperture shown in FIG. 4A where the slot or the aperture width is about the same dimension as the plasma sheath thickness by about a factor of four. However, the total ion current extracted from the grating 154, 302 depends upon the fill factor of the grating.

The sheath thickness is a function of the plasma density and the bias voltage. The sheath thickness increases with decreasing plasma density. The sheath thickness also increases with increasing bias voltage. Therefore, the desired aperture width increases with increasing implant energies. Computer simulations have shown that a one degree angular distribution of extracted ions can be achieved by reducing the aperture width to one-eighth the sheath width and by generating a relatively low density plasma (nₑ=2×10⁹ cm⁻³).

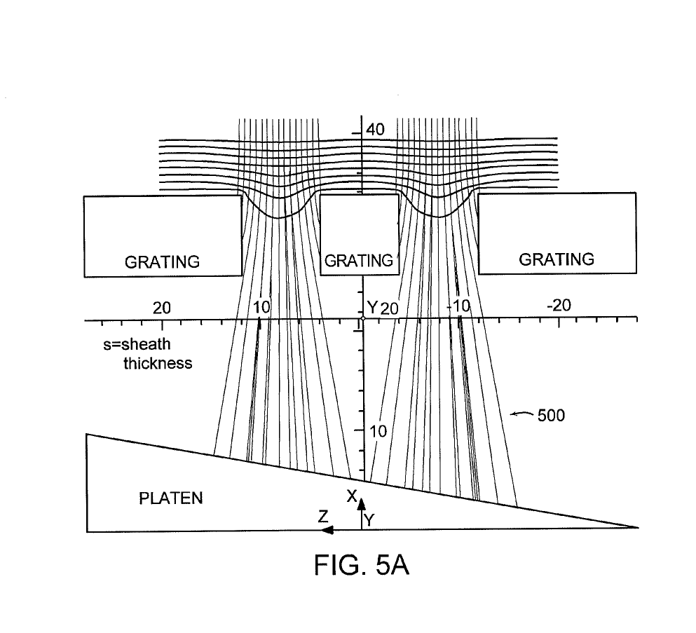

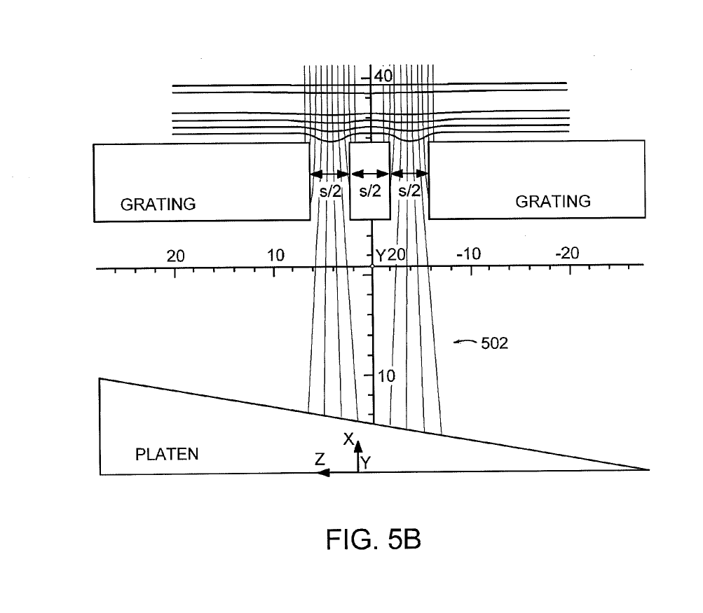

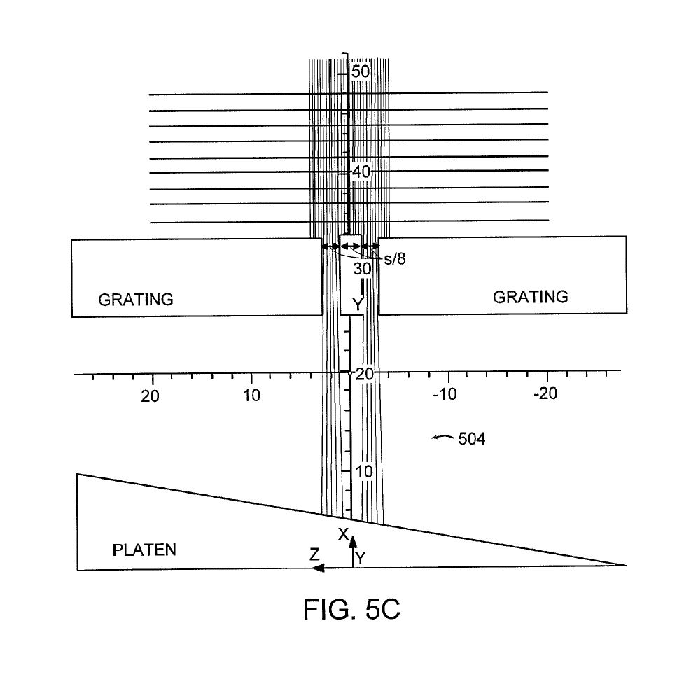

FIG. 5 shows a computer simulation of extracted ions that illustrates the interaction between two extracted ion beams. FIG. 5A shows a computer simulation 500 of extracted ions where the grating slot or aperture width and the separation between two adjacent grating slots or apertures are both equal to one sheath thickness. The computer simulation 500 shows that a separation between two adjacent slots or apertures that is equal to one sheath thickness results in no appreciable interaction between the two extracted ion beams.

FIG. 5B shows a computer simulation 502 of extracted ions where the slot or aperture width and the separation between two adjacent slots or apertures are both equal to one-half the sheath thickness. The computer simulation 502 shows that a separation between two adjacent slots or apertures that is equal to one-half the sheath thickness results in no appreciable interaction between the two extracted ion beams.

FIG. 5C shows a computer simulation 504 of extracted ions where the slot or aperture width and the separation between two adjacent slots or apertures are both equal to one-eighth the sheath thickness. The computer simulation 504 shows that a separation between two adjacent slots or apertures that is equal to one-eighth the sheath thickness also results in no appreciable interaction between the two extracted ion beams. Using slot or aperture widths that are equal to one-eighth the sheath thickness with a fill factor of 0.5 results in relatively low angular distribution that is about +1 degree (when nₑ=2×10⁹ cm⁻³) and a relatively uniform ion flux.

### EQUIVALENTS

While the present teachings are described in conjunction with various embodiments and examples, it is not intended that the present teachings be limited to such embodiments. On the contrary, the present teachings encompass various alternatives, modifications and equivalents, as will be appreciated by those of skill in the art, may be made therein without departing from the spirit and scope of the invention as defined by the appended claims.

What is claimed is:

1. A method of tilted plasma doping, the method comprising:
generating a plasma containing dopant ions in a chamber, the chamber containing a grating having a plurality of apertures, wherein plasma sheath of the plasma has a thickness greater than aperture width of the apertures; and
orienting at least one of a target and the grating so that the dopant ions extracted from the grating impact the target at a non-normal angle of incidence.

2. The method of claim 1 wherein the non-normal angle of incidence is chosen to achieve a predetermined lateral straggle of dopant ions in the target.

3. The method of claim 1 wherein the non-normal angle of incidence is chosen to reduce channeling of dopant ions into the target.

4. The method of claim 1 further comprising biasing at least one of the grating and the target.

5. The method of claim 4 wherein the biasing the at least one of the grating and the target comprises biasing the grating and the target synchronously in time.

6. The method of claim 4 wherein the biasing the at least one of the grating and the target comprises biasing the grating and the target asynchronously in time.

7. The method of claim 4 wherein the biasing the at least one of the grating and the target comprises pulsing at least one of the grating and the target at a pulse frequency.

8. The method of claim 7 wherein the pulse frequency is proportional to a scan velocity of at least one of the grating and the target.

9. The method of claim 1 further comprising periodically biasing the grating to a potential that at least partially neutralizes charge on or proximate to the target.

10. The method of claim 1 further comprising biasing the target at a potential that is positive with respect to the grating in order contain secondary electrons generated by the target.

11. The method of claim 1 further comprising periodically grounding the grating at ground potential to at least partially neutralize charge on or proximate to the target.

12. The method of claim 1 further comprising absorbing electrons generated by the target with a surface having a potential at ground potential.

13. The method of claim 1 further comprising applying a magnetic field in a region between the grating and the target to trap at least a portion of electrons that are located proximate to the target.

14. The method of claim 1 further comprising translating at least one of the target and the grating relative to the other of the target and the grating in at least one direction in order to improve uniformity of the dopant ions impacting the target.

15. The method of claim 1 further comprising rotating at least one of the target and the grating relative to the other of the target and the grating.

16. The method of claim 1 further comprising dithering at least one of the target and the grating.

17. The method of claim 1 further comprising orienting a second grating adjacent to the first grating so that dopant ions extracted from the second grating impact the target at the non-normal angle of incidence.

18. The method of claim 20 wherein a potential of the second grating is different from a potential of the grating.

19. A method of trench sidewall doping, the method comprising:
positioning a device on a platen that is positioned in a chamber, the chamber comprising a grating having a plurality of apertures;
generating a plasma having a plasma sheath, the plasma sheath having a thickness greater than aperture width of the apertures;
orienting at least one of the device and the grating so that the dopant ions extracted from the grating impact the device at a non-normal angle of incidence; and
biasing at least one of the grating and the device so that dopant ions in the plasma are extracted from the grating and impact the device at the non-normal angle of incidence.

20. A method of plasma processing, the method comprising:
generating a plasma in a plasma chamber having a grating, the grating having a plurality of apertures, the plasma having plasma sheath having a thickness greater than aperture width of the apertures; and
orienting at least one of the device and the grating so that the dopant ions extracted through the apertures of the grating impact the device at a non-normal angle of incidence.
